(19) United States
(12) Patent Application Publication
(10) Pub. No.: US 2005/0082650 A1
(43) Pub. Date: Apr. 21, 2005

(54) Integrated circuit packaging system

(76) Inventors: Chee Choong Kooi, Penang (MY); Lai Yin Men, Seremban (MY)

Correspondence Address: BUCKLEY, MASCHOFF, TALWALKAR LLC, 5 ELM STREET, NEW CANAAN, CT, 06840, US

(21) Appl. No.: 10/689,998

(22) Filed: Oct. 21, 2003

(51) Int. Cl. H01L 23/02

(52) U.S. Cl. 257/678

(57) ABSTRACT

A system may include an integrated circuit die, an integrated circuit package coupled to a first face of the integrated circuit die, mold compound in contact with the integrated circuit die and the integrated circuit package, and an overlayer coupled to the mold compound and to a second face of the integrated circuit die.

### BACKGROUND

Many systems exist for packaging an integrated circuit (IC) die. These packaging systems may electrically couple an IC die to various external elements, and may provide thermal and physical protection to the IC die. Some packaging systems include mold compound disposed around an IC die to physically protect the IC die.

Mold compound may comprise a stiff material surrounding an IC die that is coupled to an IC package. In some instances, mold compound may be susceptible to separating from the IC die, from the IC package, and/or from underfill material residing between the IC die and the IC package. This separation may compromise the reliability and/or quality of a packaging system.

### BRIEF DESCRIPTION OF THE DRAWINGS

FIG. 1 is a side cross-sectional view of an apparatus according to some embodiments.

FIG. 2 is a diagram of a process to fabricate the FIG. 1 apparatus according to some embodiments.

FIG. 3 is a top view of an IC package substrate according to some embodiments.

FIG. 4 is a bottom view of an IC die according to some embodiments.

FIG. 5 is a top view of an IC package substrate having a plurality of IC die attached thereto according to some embodiments.

FIG. 6 is a side cross-sectional view of an IC package substrate and a plurality of IC die according to some embodiments.

FIG. 7 is a top view of an IC package substrate, a plurality of IC die, and mold compound according to some embodiments.

FIG. 8 is a top view of an apparatus according to some embodiments.

FIG. 9 is a side cross-sectional view of an apparatus according to some embodiments.

FIG. 10 is a top view of an IC package substrate and overlayer material according to some embodiments.

FIG. 11 is a side cross-sectional view of an apparatus according to some embodiments.

FIG. 12 is a diagram of a system according to some embodiments.

### DETAILED DESCRIPTION

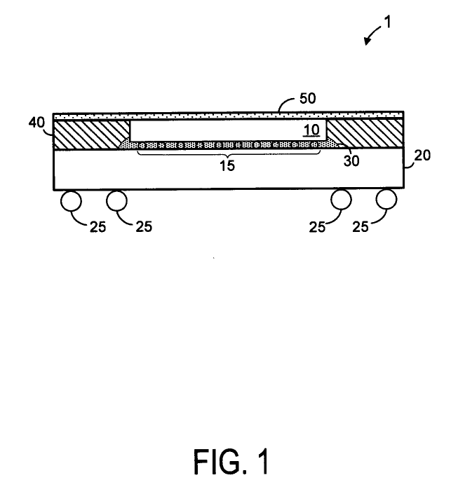

FIG. 1 is a cross-sectional side view of apparatus 1 according to some embodiments. Apparatus 1 includes IC die 10 coupled to IC package 20. IC die 10 includes integrated electrical devices and may be fabricated using any suitable material and fabrication techniques. IC die 10 may provide one or more functions. In some embodiments, IC die 10 comprises a microprocessor, a network processor, or a transceiver having a silicon substrate.

Electrical contacts 15 are coupled to IC die 10 and may be electrically coupled to the electrical devices that are integrated into IC die 10. Electrical contacts 15 are also coupled to electrical contacts (not shown) of IC package 20. In some embodiments, die 10 is electrically coupled to IC package 20 via wirebonds in addition to or as an alternative to electrical contacts 15. IC package 20 may comprise any ceramic, organic, and/or other suitable material.

IC package 20 comprises solder balls 25 for carrying power and I/O signals between elements of apparatus 1 and external devices. For example, solder balls 25 may be mounted directly to a motherboard (not shown) or onto an interposer that is in turn mounted directly to a motherboard. Alternative interconnects such as through-hole pins may be used instead of solder balls 25 to mount apparatus 1 to a motherboard, a socket, or another substrate.

Underfill material 30 encapsulates the electrical coupling between IC die 10 and IC package 20 and may therefore protect the coupling from exposure to environmental hazards.

Underfill material 30 may also assist the mechanical coupling between IC die 10 and IC package 20. For example, electrical contacts 15 may experience mechanical stress when heated due to a difference between the coefficient of thermal expansion (CTE) of IC die 10 and the CTE of IC package 20. Underfill material 30 may address this mismatch by distributing the stress away from electrical contacts 15.

Mold compound 40 is in contact with IC die 10 and with IC package 20. In some embodiments, mold compound 40 surrounds a perimeter of IC die 10. Mold compound 40 may comprise a stiff material that provides stiffness to apparatus 1 and physical protection to IC die 10 and to IC package 20. This increased stiffness may also reduce the mechanical stress experienced by electrical connections 15.

Overlayer 50 is coupled to mold compound 40 and to IC die 10. In the illustrated embodiment, overlayer 50 is coupled to a face of IC die 10 that is opposite from a face of IC die 10 to which IC package 20 is coupled. Overlayer 50 may comprise any suitable material according to some embodiments, including but not limited to any currently- or hereafter-known die attach film and/or paste. Overlayer 50 may comprise thermally-conductive material, such as a metal-filled die attach film.

Overlayer 50 may, in some embodiments, reduce a tendency of mold compound 40 to delaminate from die 10, underfill material 30, and/or IC package 20. Overlayer 50 may reduce an overall height of apparatus 1 and/or may provide greater dissipation of heat away from IC die 10 in comparison to other systems.

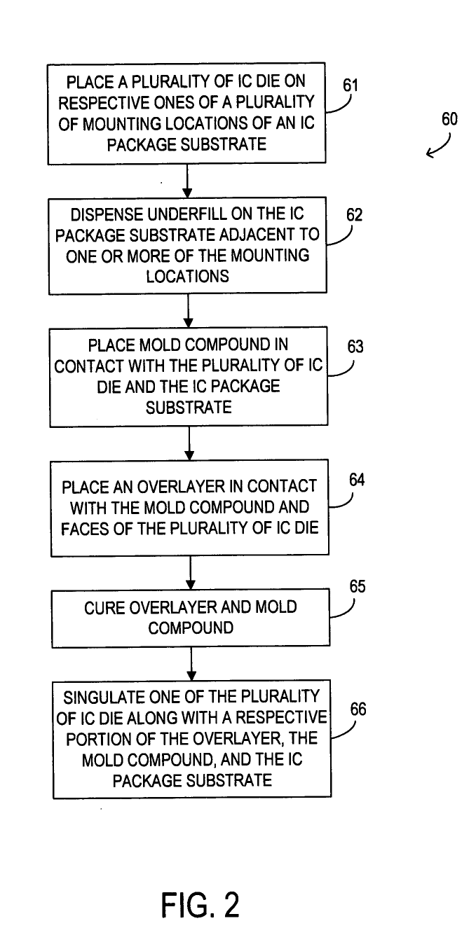

FIG. 2 is a diagram of process 60 to fabricate apparatus 1 according to some embodiments. Process 60 may be executed by one or more devices, and all or a part of process 60 may be executed manually. Process 60 may be executed by an entity different from an entity that manufactures IC die 10.

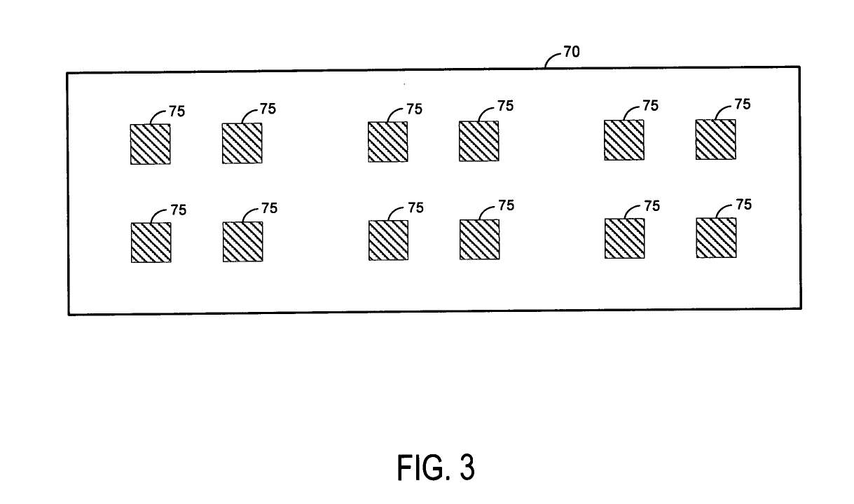

Initially, at 61, a plurality of IC die are placed on respective ones of a plurality of mounting locations of an IC package substrate. Descriptions of an IC package substrate and an IC die are now provided in order to explain some embodiments of 61. FIG. 3 shows IC package substrate 70 and mounting locations 75 according to some embodiments. IC package substrate 70 may be composed of any suitable IC package material, including but not limited to an organic laminated glass-weave polymer.

Mounting locations 75 are disposed in a matrix array package (MAP) configuration. Mounting locations 75 may comprise any type of electrical contacts for electrically coupling an IC die to routing vias and electrical traces within IC package substrate 70. According to some embodiments, IC package substrate 70 and mounting locations 75 may be fabricated using any currently- or hereafter-known MAP fabrication method.

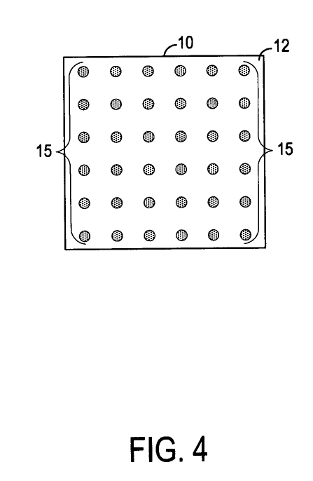

FIG. 4 shows face 12 of IC die 10 according to some embodiments. Face 12 of IC die 10 includes electrical contacts 15. Electrical contacts 15 may be electrically coupled to the electrical devices that are integrated into IC die 10. The electrical devices may reside between a substrate of IC die 10 and electrical contacts 15 in a “flip-chip” arrangement. In some embodiments, such a substrate resides between the electrical devices and electrical contacts 15.

Electrical contacts 15 may comprise Controlled Collapse Chip Connect (C4) solder bumps, and/or gold and/or nickel-plated copper contacts fabricated upon IC die 10. In this regard, electrical contacts 15 may be recessed under, flush with, or extending above face 12 of IC die 10.

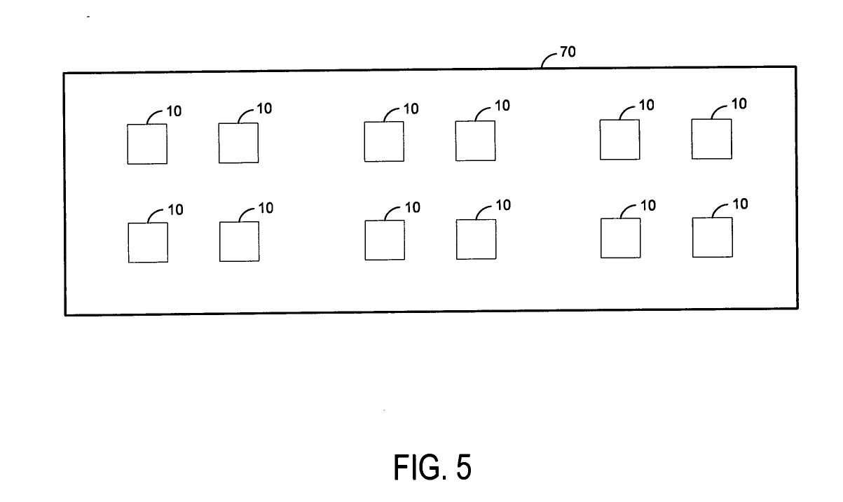

At 61, the plurality of die 10 may be placed on respective ones of mounting locations 75 using a pick-and-place machine. FIG. 5 is a top view of IC package substrate 70 after a plurality of IC die 10 are placed thereon at 61. Electrical contacts 15 of the plurality of IC die 10 are then soldered to electrical contacts of respective mounting locations 75. Such soldering may be accomplished using conventional reflow techniques.

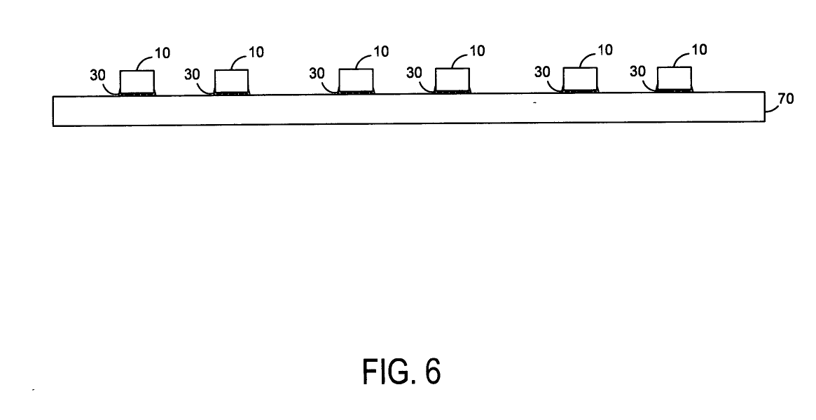

Underfill material is dispensed on IC package substrate 70 adjacent to one or more mounting locations 75 at 62. The dispensed underfill material may comprise a capillary flow underfill material according to some embodiments. Generally, capillary flow underfill material is placed next to an IC die-substrate interface and is “pulled” into the interface by surface energy and/or capillary action. Energy may then be applied to the underfill material to transform the material into a protective inert polymer. FIG. 6 is a cross-sectional side view further illustrating the arrangement of IC package substrate 70, IC die 10, and underfill material 30 after 62 and according to some embodiments.

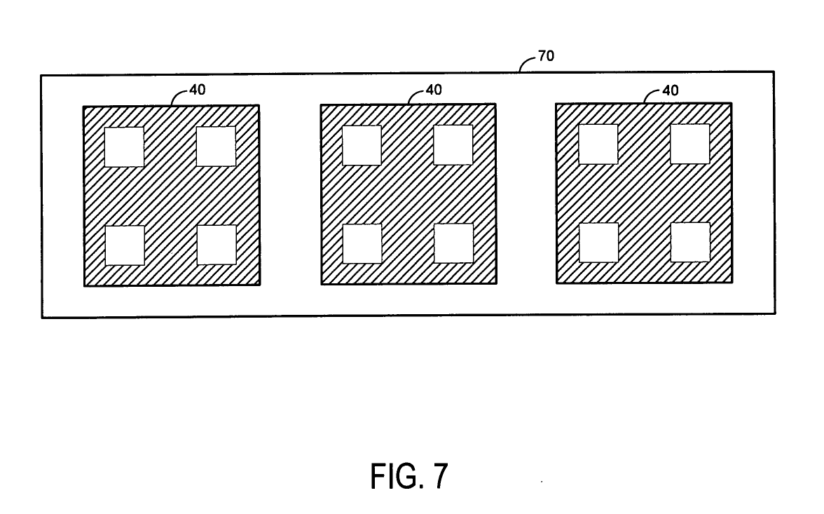

At 63, mold compound is placed in contact with the plurality of IC die 10 and with IC package substrate 70. In some embodiments, a mold is used to place a portion of mold compound 40 in contact with each “cluster” of IC die 10 as shown in FIG. 7. A face of each IC die 10 remains at least partially uncovered.

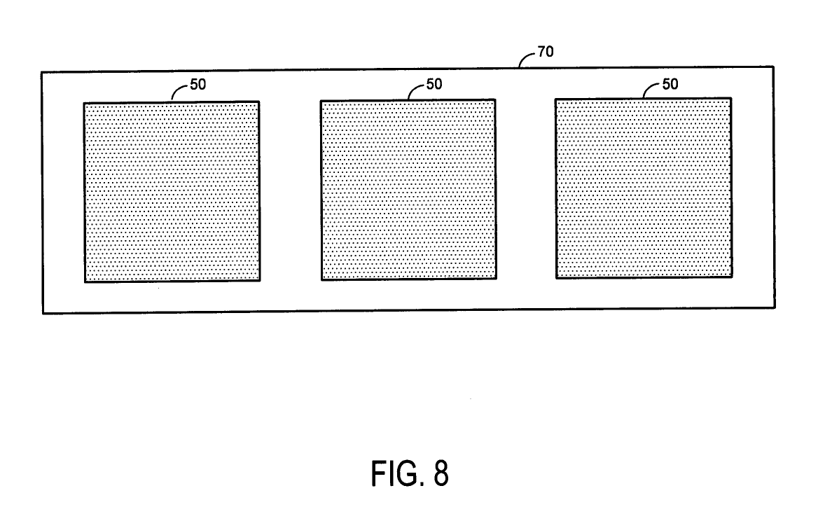

Next, overlayer 50 is placed in contact with molding compound 40 and with the exposed faces of the plurality of IC die 10 at 64. FIG. 8 illustrates overlayer 50 after 64 in accordance with some embodiments. Overlayer 50 may comprise a solid film that is “picked-and placed” on a respective cluster of IC die 10, and/or may comprise a paste that is dispensed and smeared to result in the arrangement illustrated in FIG. 8.

Mold compound 40 and overlayer 50 are then cured at 65. Curing may involve subjecting mold compound 40 and overlayer 50 to elevated heat. In some embodiments, underfill material 30 is also cured at 65. One or more of compound 40, overlayer 50, and/or underfill material 30 may be partially and/or completely cured prior to 65. Curing temperatures and sequences may depend on the specific fabrication techniques and materials used in various embodiments.

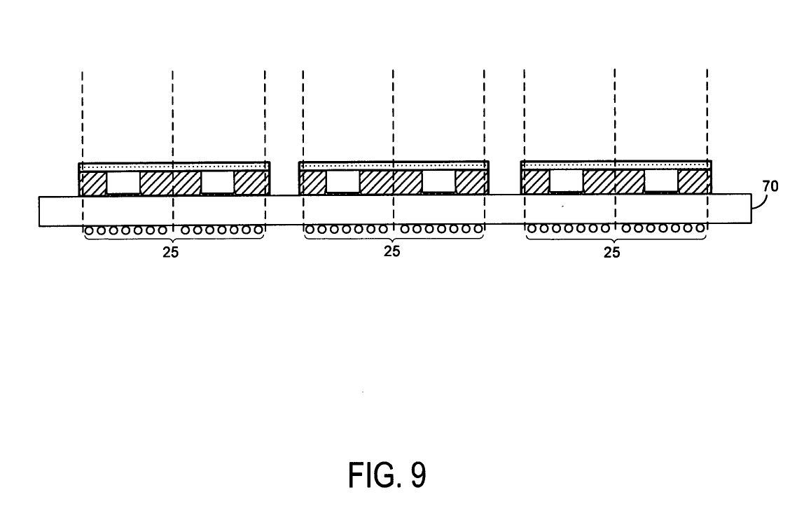

At 66, one or more of IC die 10 are singulated along with a respective portion of overlayer 50, mold compound 40, and IC package substrate 70. FIG. 9 is a cross-sectional side view of the FIG. 8 apparatus according to some embodiments. As shown, solder balls 25 have been attached to corresponding electrical contacts (not shown) of IC package substrate 70. Solder balls 25 may be attached by turning substrate 70 upside down, placing solder balls 25 at appropriate locations, and reflowing solder balls 25. Such reflowing may also serve to cure compound 40, overlayer 50, and/or underfill material 30.

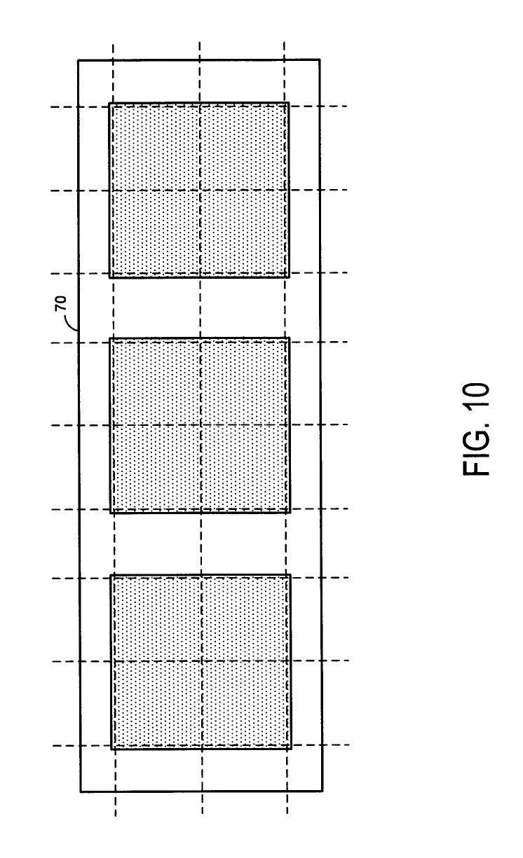

The dashed lines of FIG. 9 represent where IC package 70 may be cut at 66 in order to singulate one or more of IC die 10. FIG. 10 is a top view of IC package 70 further showing a cutting pattern according to some embodiments. Singulation at 66 may proceed using any currently- or hereafter-known methods, including saw singulation.

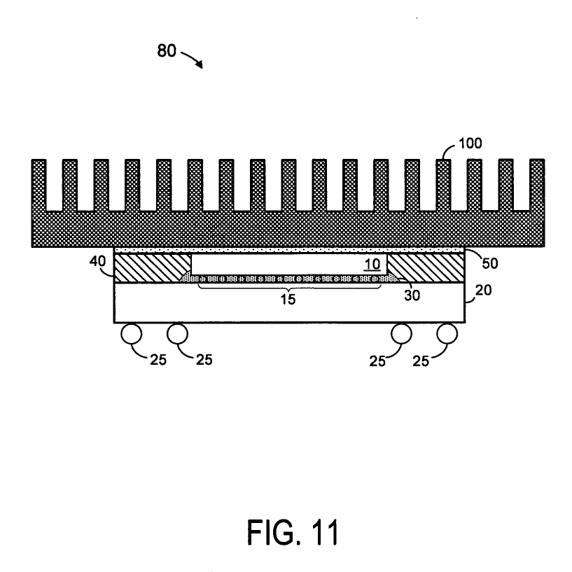

FIG. 11 illustrates apparatus 80 according to some embodiments. The elements of apparatus 80 may be identical to similarly-numbered elements of apparatus 1. Heat sink 100 is coupled to overlayer 50. Heat sink 100 may comprise any currently- or hereafter-known passive or active heat sink. Overlayer 50 may include thermally-conductive elements, and/or a thermally-conductive paste or other material may be disposed between overlayer 50 and heat sink 100. Such an arrangement may improve the conductivity of heat away from die 10.

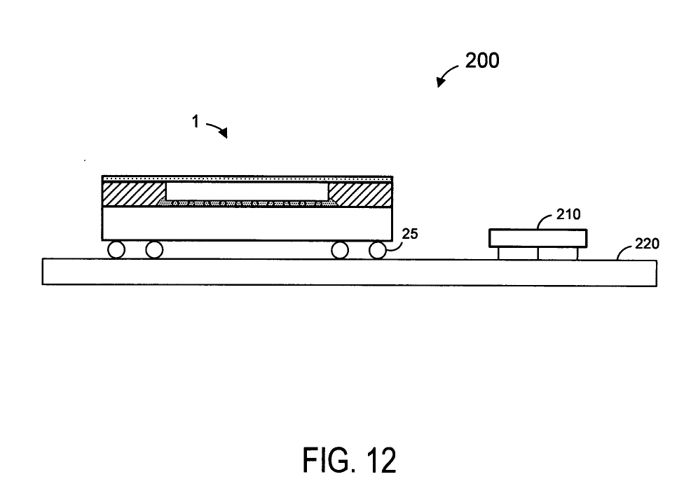

FIG. 12 is a cross-sectional side view of system 200 according to some embodiments. System 200 may comprise components of a server platform. System 200 includes apparatus 1 as described above, memory 210 and motherboard 220. Apparatus 1 may comprise a microprocessor.

Motherboard 220 may electrically couple memory 210 to apparatus 1. More particularly, motherboard 220 may comprise a memory bus (not shown) that is electrically coupled to solder balls 25 and to memory 210. Memory 210 may comprise any type of memory for storing data, such as a Single Data Rate Random Access Memory, a Double Data Rate Random Access Memory, or a Programmable Read Only Memory.

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

1. An apparatus comprising:
an integrated circuit die;
an integrated circuit package coupled to a first face of the integrated circuit die;
mold compound in contact with the integrated circuit die and the integrated circuit package; and
an overlayer coupled to the mold compound and to a second face of the integrated circuit die.

2. An apparatus according to claim 1, further comprising:
underfill material disposed between the integrated circuit die and the integrated circuit package.

3. An apparatus according to claim 1, wherein the overlayer comprises thermally conductive material.

4. An apparatus according to claim 1, wherein the overlayer comprises cured die attach film.

5. An apparatus according to claim 1, wherein the overlayer comprises cured die attach paste.

6. An apparatus comprising:
an integrated circuit package substrate;
a plurality of integrated circuit die, a first face of each of the plurality of integrated circuit die attached to the integrated circuit package substrate; and
mold compound in contact with the plurality of integrated circuit die and the integrated circuit package substrate; and
an overlayer coupled to the mold compound and to a second face of each of the plurality of integrated circuit die.

7. An apparatus according to claim 6, further comprising:
underfill material disposed between the first face of each of the plurality of integrated circuit die and the integrated circuit package substrate.

8. An apparatus according to claim 6, wherein the overlayer comprises thermally conductive material.

9. An apparatus according to claim 6, wherein the overlayer comprises cured die attach film.

10. An apparatus according to claim 6, wherein the overlayer comprises cured die attach paste.

11. A method comprising:
placing an overlayer in contact with mold compound and a first face of an integrated circuit die,
wherein a second face of the integrated circuit die is coupled to an integrated circuit package, and
wherein the mold compound is in contact with the integrated circuit die and the integrated circuit package.

12. A method according to claim 11, further comprising:
singulating one of the plurality of integrated circuit die and a respective mounting location of the integrated package substrate.

13. A method according to claim 11, wherein the overlayer comprises thermally conductive material.

14. A method according to claim 11, wherein the overlayer comprises cured die attach film.

15. A method according to claim 11, wherein the overlayer comprises cured die attach paste.

16. A system comprising:
a microprocessor comprising:
an integrated circuit die;
an integrated circuit package coupled to a first face of the integrated circuit die;
mold compound in contact with the integrated circuit die and the integrated circuit package; and
an overlayer coupled to the mold compound and to a second face of the integrated circuit die; and
a double data rate memory electrically coupled to the microprocessor.

17. A system according to claim 16, wherein the overlayer comprises thermally conductive material.

18. A system according to claim 16, further comprising:
a motherboard electrically coupled to the microprocessor and to the memory.
